(19) United States
(12) Patent Application Publication
(10) Pub. No.: US 2026/0344421 A1
(43) Pub. Date: Oct. 29, 2026

(54) METHOD OF MANUFACTURING SEMICONDUCTOR DEVICES AND CORRESPONDING SEMICONDUCTOR DEVICE

(71) Applicant: STMicroelectronics International N.V., Geneva (CH)

(72) Inventors: Guendalina CATALANO, Milano (IT); Thomas GOTTARDI, Agrate Brianza, MB (IT)

(73) Assignee: STMicroelectronics International N.V., Geneva (CH)

(21) Appl. No.: 19/462,045

(22) Filed: Jan. 28, 2026

(30) Foreign Application Priority Data
Jan. 29, 2025 (IT) 102025000001554

(51) Int. Cl. H10W 40/22; H10W 40/00; H10W 74/01; H10W 74/10; H10W 90/00

(52) U.S. Cl. CPC H10W 40/226; H10W 40/03; H10W 74/01; H10W 74/111; H10W 90/724; H10W 90/726

(57) ABSTRACT

Electrically conductive pillars of a semiconductor die are mounted onto a substrate. The substrate and semiconductor die mounted thereon are encapsulated in an encapsulation of electrically insulating material. The encapsulation of electrically insulating material has a first surface at the substrate and a second surface opposite the first surface. Electrically insulating material is removed from the second surface of the encapsulation to form an opening which exposes a back surface of the semiconductor die opposite said active surface. A thermally conductive layer is provided in the opening in heat transfer relationship with the exposed back surface of the semiconductor die to provide a heat dissipation structure.

### PRIORITY CLAIM

This application claims the priority benefit of Italian Application for Patent No. 102025000001554 filed on Jan. 29, 2025, the content of which is hereby incorporated by reference in its entirety to the maximum extent allowable by law.

### TECHNICAL FIELD

The description relates to manufacturing semiconductor devices.

One or more embodiments may be applied to manufacturing integrated circuit (IC) semiconductor devices such as flip-chip semiconductor devices.

### BACKGROUND

In current manufacturing processes of (integrated circuit (IC)) semiconductor devices, a semiconductor die or chip is mounted on a substrate such as a leadframe, for instance, and subsequently encapsulated in an electrically insulating encapsulation that provides a protective, plastic package to the semiconductor die.

The substrate onto which the semiconductor die is mounted is exposed at a surface of the electrically insulating package, facilitating mounting the device onto a final supporting substrate (a printed circuit board (PCB) for instance) via soldering.

Heat generated during normal operation of a device, due to power dissipation within the semiconductor die, for instance, may be transferred to the final supporting substrate via the (thermally conductive) substrate which provide thermal coupling between the semiconductor die and the final supporting substrate, thus facilitating dissipation of heat.

In certain semiconductor devices such as power devices for automotive or industrial application, for instance, considerable heat may be generated in response to the (relatively) high intensity currents that are transferred in the device.

For instance, in power flip-chip devices, dissipation of heat only via the thermally conductive substrate may lead to inadequate thermal performance of the (flip-chip) semiconductor device.

Reference is made to United States Patent Application Publication Nos. 2024/0203836 A1, 2014/0117523 A1, 2016/0307830 A1, 2022/0367328 A1 and 2016/0197066 A1, and United States Patent No. 10,115,645 B1, all of which are incorporated herein by reference, which provide background information in the related technological area.

There is a need in the art to overcome the drawbacks discussed in the foregoing.

### SUMMARY

One or more embodiments relate to a method.

One or more embodiments relate to a corresponding semiconductor device.

Solutions as described herein may advantageously be applied to semiconductor devices such as flip-chip semiconductor devices, wherein an integrated circuit, (IC) semiconductor die is mounted onto a substrate with electrically conductive pillars between the semiconductor die and the substrate.

Solutions as described herein involve providing an electrically insulating encapsulation to the semiconductor die mounted on the substrate and, subsequently, partially removing electrically insulating material from a surface of the encapsulation to expose a back surface of the semiconductor die.

In solutions as described herein, a thermally conductive layer is formed onto the back surface of the semiconductor die that is left uncovered by the electrically insulating encapsulation. A thermally conductive layer is thus exposed at a surface of the device, promoting dissipation of heat generated during (normal) operation of the device.

In solutions as described herein, the thermally conductive layer may be formed via an additive manufacturing technique such as laser induced forward transfer, LIFT, for instance.

In solutions as described herein, the thermally conductive layer may be provided with protrusions (fins, for instance) that improve heat dissipation of the semiconductor device.

Solutions as described herein may advantageously be applied to devices comprising a substrate such as a leadframe or a laminate substrate, for instance.

### BRIEF DESCRIPTION OF THE DRAWINGS

One or more embodiments will now be described, by way of example only, with reference to the annexed figures, wherein:

FIG. 1 is a cross-sectional view illustrative of the structure of a semiconductor device;

FIGS. 2 and 3 are cross-sectional views illustrative of processing steps applied to a semiconductor device as illustrated in FIG. 1;

FIG. 4 is a cross-sectional view illustrative of advantageous embodiments;

FIGS. 5 and 6 are cross-sectional views illustrative of processing steps; and

FIG. 7 is a cross-sectional view illustrative of embodiments applied to a semiconductor device comprising a laminate substrate.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular configurations, structures, or characteristics may be combined in any adequate way in one or more embodiments. The references used herein are provided merely for convenience and hence do not define the extent of protection or the scope of the embodiments.

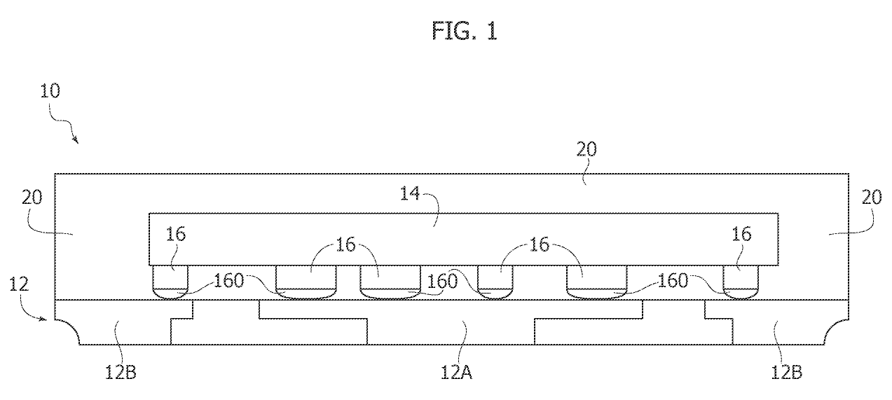

FIG. 1 is a cross-sectional view illustrative of the structure of an (integrated circuit (IC)) semiconductor device 10 of the type conventionally referred to as Flip-Chip Quad Flat No Leads (FC-QFN).

The device 10 exemplified in FIG. 1 comprises an electrically conductive substrate or leadframe 12 comprising a die pad 12A having an array of electrically conductive leads 12B arranged peripherally of the die pad 12A.

The designation “leadframe” (or “lead frame”) is currently used (see, for instance the USPC Consolidated Glossary of the United States Patent and Trademark Office) to indicate a metal frame that provides support for an integrated circuit chip or die (the terms die/dice and chip/chips are herein regarded as synonymous) as well as electrical leads to interconnect the integrated circuit in the die to other electrical components or contacts.

As known to those skilled in the art, a leadframe 12 can be of the pre-molded type, that is a type of leadframe comprising a sculptured metal (copper, for instance) structure formed by etching a metal sheet and comprising empty spaces that are filled by a resin “pre-molded” on the sculptured metal structure.

A semiconductor device 10 as illustrated in FIG. 1 comprises also: a semiconductor (Si, SiC, GaN for instance) die 14 mounted onto the substrate 12, and an electrically insulating encapsulation 20 that provides a protective plastic package to the device 10.

A device 10 as illustrated in FIG. 1 may be configured to be mounted on a (final) supporting substrate such as a printed circuit board (PCB) for instance.

The semiconductor die 14 in the device 10 illustrated in FIG. 1 is flip-chip mounted onto the substrate 12, that is, mounted via electrically conductive pillars 16 arranged between a surface of the (integrated circuit, IC) semiconductor die 14 and the top/front surface of the substrate 12 at the die pad 12A and leads 12B.

The electrically conductive pillars 16 provide electrical coupling between the substrate 12 and die bonding pads at an active surface of the semiconductor die 14 (the bottom surface of the semiconductor die 14 illustrated in the figures) that provide electrical contact points for the integrated circuit embedded in the semiconductor die 14 (the die bonding pads are not visible in the figures for scale reasons).

In embodiments where the substrate 12 comprises a leadframe, the electrically conductive pillars 16 provide electrical coupling between the semiconductor die 14 and the portions of the leadframe 12 (that is, the leads 12B and the die pad 12A).

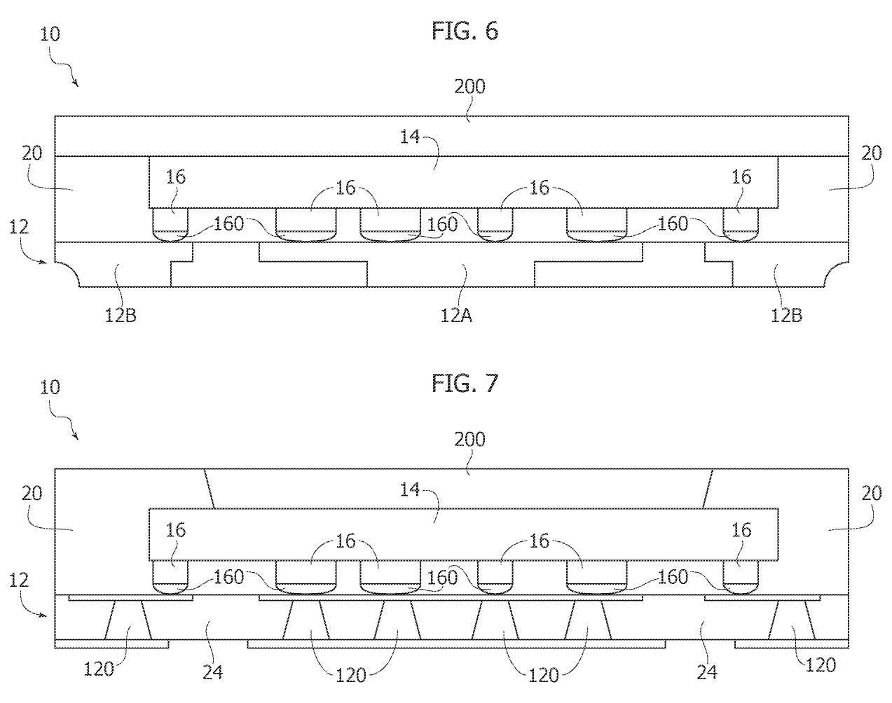

As discussed in the following (with reference to FIG. 6, for instance), embodiments of the present description may be applied also in devices wherein the substrate 12 comprises a laminate substrate (a land grid array (LGA) or a ball grid array (BGA) substrate, for instance).

Electrically conductive pillars 16 may be provided at the active surface of the semiconductor die 14 by growing electrically conductive material (a metallic material such as copper, for instance) at the die bonding pads at the active surface of the semiconductor die 14. It is noted that in conventional manufacturing processes of semiconductor devices, electrically conductive pillars 16 may be concurrently formed for a plurality of semiconductor dice in a wafer (a processing step oftentimes referred to as “wafer bumping”) that is subsequently partitioned into a plurality of semiconductor dice having electrically conductive pillars provided at the active surface thereof. The semiconductor dice 14 are thus (flip-chip) mounted onto the substrate 12, with solder material 160 at the distal portion of the electrically conductive pillars 16 that facilitates forming the desired electrical coupling between the pillars and the substrate 12.

Solutions as described herein may advantageously be applied also in cases where the electrically conductive pillars 16 are formed by growing electrically conductive material (again, a metallic material such as copper, for instance) onto regions of the substrate 12.

That is, solutions as described herein may involve mounting a semiconductor die 14 onto a substrate 12 (a leadframe or a laminate substrate, for instance) with electrically conductive pillars 16 arranged between an active surface of the semiconductor die 14 and a die-mounting (top or front) surface of the substrate 12 (irrespective of whether the electrically conductive pillars are grown onto the substrate or onto the active surface of the semiconductor die).

The semiconductor device 10 illustrated in FIG. 1 may be a power semiconductor device, that is, a semiconductor device 10 configured to operate at relatively high voltages and relatively high intensity currents. To that effect the electrically conductive pillars 16 may comprise: first electrically conductive pillars 16 configured to provide power electrical coupling; and second electrically conductive pillars 16 configured to provide signal electrical coupling.

First/second electrically conductive pillars 16 are illustrated in FIG. 1 as larger/smaller pillars, respectively (indicated with the same reference 16 for simplicity). In other words, the pillars have at least two different sizes in terms of, for example, a cross-sectional area.

As illustrated in FIG. 1, the substrate (a thermally and electrically conductive leadframe, for instance) onto which the semiconductor die is mounted is exposed at a surface of the electrically insulating encapsulation 20. This facilitates: mounting the device onto a final supporting substrate (a printed circuit board, PCB, for instance), via soldering, for instance; and transferring heat generated during normal operation of the device 10 to the final supporting substrate via the (thermally conductive) substrate which provide thermal coupling between the semiconductor die and the final supporting substrate.

In power semiconductor devices as exemplified in FIG. 1, considerable heat may generate during normal operation of the device 10 and heat dissipation via the substrate 12 may be inadequate or insufficient.

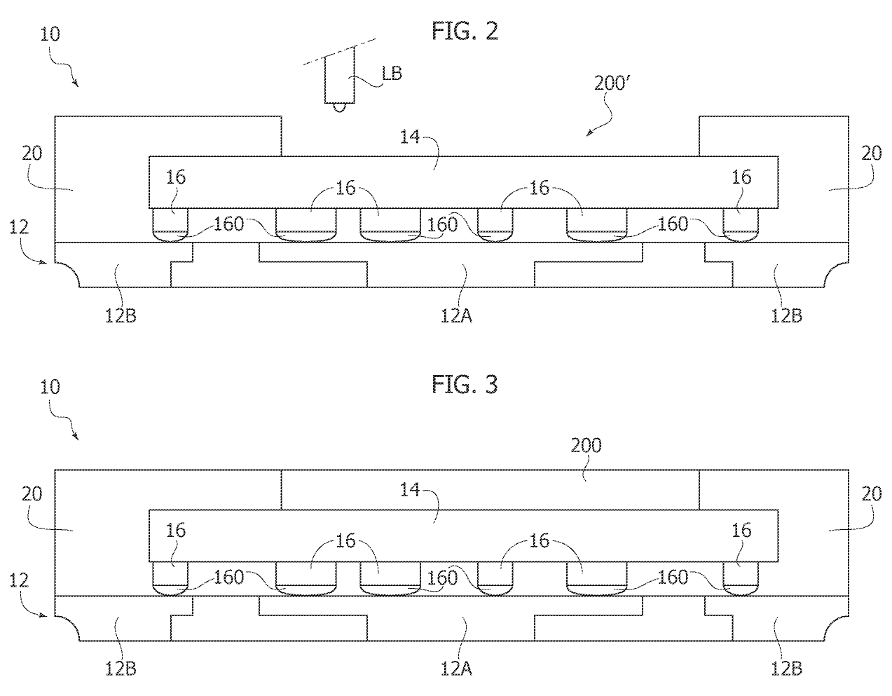

FIGS. 2 and 3 are cross-sectional views illustrative of processing steps applied to a semiconductor device 10 as illustrated in FIG. 1.

With reference to FIG. 2, a portion of the electrically insulating material of the encapsulation 20 is removed to expose a (back) surface of the semiconductor die 14.

As illustrated, laser beam energy LB may be applied to the top/front surface of the encapsulation 20 of electrically insulating material (an epoxy resin, for instance, molded onto the substrate 12 having the semiconductor die 14 mounted thereon) to partially remove (ablate) encapsulation material therefrom.

A recess or cavity 200’ may be formed at the top/front surface of the semiconductor device 10, wherein the back surface 14A of the semiconductor die 14 (that is, the surface opposite the active surface of the semiconductor die 14) provides a bottom surface of the cavity or recess 200’.

Said otherwise, at least a portion of the back surface 14A of the semiconductor die 14 is exposed (that is, left uncovered by the electrically insulating material of the encapsulation 20) in response to electrically insulating material of the encapsulation 20 being removed from the top/front surface of the encapsulation 20.

Referring now to FIG. 3, thermally conductive material may be dispensed at the cavity or recess 200’ to form therein a layer of thermally conductive material 200 in thermal contact with the back surface 14A of the semiconductor die 14. That is, a thermally conductive layer 200 is formed in heat transfer relationship with the back surface 14A of the semiconductor die 14.

The thermally conductive layer 200 facilitates dissipating heat generated by the (IC) semiconductor die 14 during operation of the device 10. In a leadframe 12 based semiconductor device 10 as illustrated in FIG. 3, heat may be dissipated via the thermally (and electrically) conductive leadframe 12 and via the thermally conductive layer 200 acting as a heat sink for the device 10.

The thermally conductive layer 200 may be provided as a slab of thermally conductive material applied (via a pick-and-place equipment, for instance) at the cavity 200’ formed in the top/front surface of the encapsulation 20. The thermally conductive layer 200 may be attached to the back surface 14A of the semiconductor die 14 via a thermally conductive glue, in order to facilitate transfer of heat from the semiconductor die 14 to the thermally conductive layer 200.

Advantageously, the thermally conductive layer 200 may be provided by dispensing a thermally conductive material (a metallic material such as copper, for instance) at the cavity 200’ via additive manufacturing techniques.

For instance, laser induced forward transfer (LIFT) may be used to provide the thermally conductive layer 200. LIFT denotes a deposition process where material from a donor tape or sheet is transferred to an acceptor substrate (here, the back surface of the semiconductor die 14A) facilitated by laser pulses.

General information on the LIFT process can be found, for instance, in P. Serra, et al.: “Laser-Induced Forward Transfer: Fundamentals and Applications”, in Advanced Materials Technologies/Volume 4, Issue 1 (incorporated herein by reference).

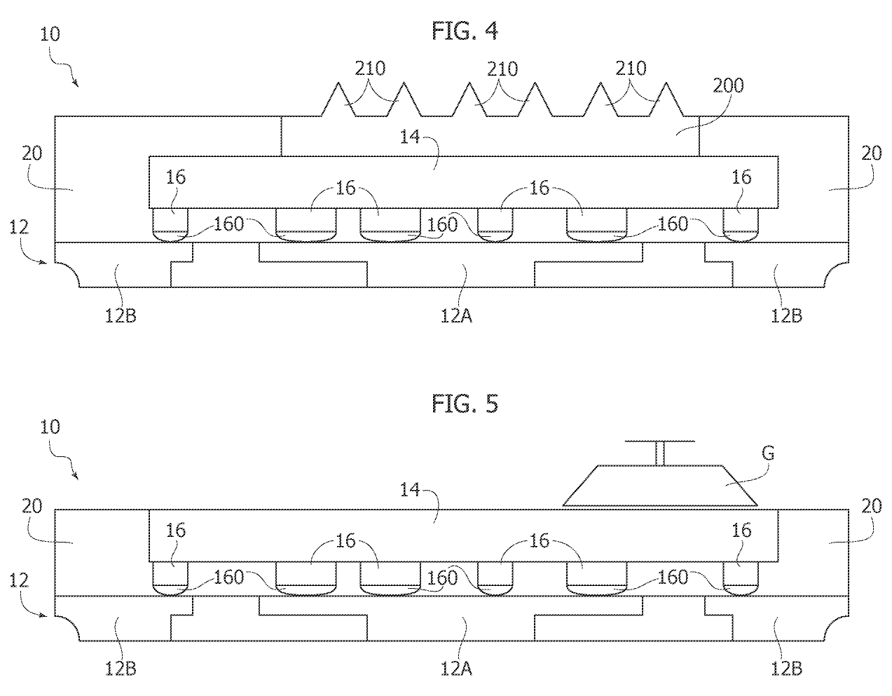

FIG. 4 is a cross-sectional view illustrative of a further embodiment wherein the thermally conductive layer 200 is provided with protrusions 210 at the top/front surface thereof.

Protrusions 210 having a desired shape may be simply formed via additive manufacturing techniques (LIFT, for instance). The protrusions 210 increase the surface of the thermally conductive layer 200 that is exposed at the top/front surface of the device 10, thus improving heat dissipation of the thermally conductive layer 200.

According to advantageous embodiments (schematically illustrated in FIG. 4), the protrusion 210 may be formed as heat-dissipating fins, that further facilitate dissipation of heat generated by the device 10.

FIGS. 5 and 6 are cross-sectional views illustrative of processing steps applied to a semiconductor device 10 as illustrated in FIG. 1.

As illustrated in FIG. 5, electrically insulating material (an epoxy resin, for instance) may be removed from the top/front surface of the encapsulation 20 via grinding (via a grinding or milling apparatus G, for instance). As illustrated, this results in the back surface 14A (for example, all of the back surface 14A) of the semiconductor die 14 being exposed, that is, left uncovered, by the electrically insulating encapsulation 20.

With reference to FIG. 6, a thermally conductive layer 200 may be provided with a layer area (notionally) equal to the area of the top/front surface of the device 10 (and for example larger in area than the back surface 14A).

As described previously, the thermally conductive layer 200 may be provided by arranging a (pre-formed) layer of thermally conductive material at the top/front surface of the device 10 (subsequent to exposing the back surface 14A of the semiconductor die 14) or by dispensing thermally conductive material (copper, for instance) via an additive manufacturing technique (such as LIFT or jetting, for instance).

FIG. 7 is illustrative of embodiments applied to a semiconductor device 10 provided with a laminate substrate 12.

As illustrated, the laminate substrate 12 (a land grind array (LDA) or a ball grid array (BGA) substrate, for instance) may comprise an electrically insulating matrix 24 (of a fiberglass based laminate material, for instance) having embedded therein electrically conductive formations 120.

The electrically conductive formations 120 provide pads at the top/front surface of the substrate 12 that are electrically coupled to the semiconductor die 14 via the electrically conductive pillars 16 (facilitated by solder material 160 provided between the distal portion of the electrically conductive pillars 16 and the pads at the top/front surface of the substrate 12).

Processing steps similar to those described with reference to FIGS. 2-6 may be performed in order to provide a semiconductor device 10 comprising a thermally conductive layer 200 in heat transfer relationship with the back surface 14A of the semiconductor die 14. A similar description is not repeated for brevity.

It is noted that the previous description refers to manufacturing a single device only for simplicity and ease of explanation. In fact, in current manufacturing processes of semiconductor devices, plural devices may be manufactured concurrently to be separated into single individual device in a final singulation.

To that effect, processing steps as described in the foregoing (with reference to FIGS. 2-6, for instance) may be performed at panel (or wafer) level, that is, performed on a panel comprising a plurality of devices 10 (as exemplified in FIG. 1) that is singulated (partitioned) into a plurality of (finished) devices 10 in a final singulation step.

For instance, processing steps described with reference to FIGS. 5 and 6 may be advantageously performed at panel level, wherein electrically insulating encapsulation material 20 is removed by grinding the panel, thus exposing a back surface 14A of a plurality of semiconductor dice 14 comprised in the panel in a same grinding step.

A thermally conductive layer 200 having size and dimensions of the panel may be arranged (attached via a thermally conductive glue, for instance) at the top/front surface of the panel (subsequently to the grinding step) to concurrently provide a thermally conductive layer 200 to the plurality of devices 10 in the panel.

Singulating the panel results in a plurality of semiconductor device 10 having a heat-dissipating thermally conductive layer 200 at the top/front surface thereof.

In summary, solutions as described herein involve mounting a semiconductor die 14 onto a substrate 12 (a leadframe or a laminate substrate, for instance) with electrically conductive pillars 16 arranged between an active surface of the semiconductor die 14 and a die-mounting surface of the substrate 12.

The electrically conductive pillars 16 provide electrical coupling between the semiconductor die 14 and the substrate 12.

The substrate 12 having the semiconductor die 14 mounted thereon is encapsulated in an encapsulation 20 of electrically insulating material (an epoxy resin, for instance, molded onto the assembly). The encapsulation 20 of electrically insulating material has a first surface at the substrate 12 and a second surface opposite the first surface.

Electrically insulating material is removed from the second surface of the encapsulation 20 to expose a back surface 14A of the semiconductor die 14 opposite the active surface.

A thermally conductive layer 200 is provided in heat transfer relationship with said exposed back surface 14A of the semiconductor die 14. The thermally conductive layer 200 facilitates dissipation of heat generated by the semiconductor die 14.

As described in the foregoing, electrically insulating encapsulation material may be removed from said second surface of the encapsulation 20 to expose said back surface 14A of the semiconductor die 14 via laser ablation LB or via grinding G.

According to embodiments of the present description, the thermally conductive layer 200 in heat transfer relationship with said exposed back surface 14A of the semiconductor die 14 may be provided via an additive manufacturing technique.

Advantageously, the thermally conductive layer 200 may be provided by dispensing thermally conductive material (a metallic material such as copper, for instance) via laser induced forward transfer (LIFT) technique.

The thermally conductive layer 200 may be formed with protrusion 210 that further facilitate dissipation of heat generated by the semiconductor die 14.

In advantageous embodiments, the protrusion 210 may be formed as heat dissipating fins 210.

Embodiments of the present description may be applied to semiconductor devices comprising a semiconductor die 14 mounted on a substrate such as a leadframe (as described with reference to FIGS. 1-6) or a laminate substrate (an LDA or a BGA laminate substrate 12, as described with reference to FIG. 7, for instance).

Without prejudice to the underlying principles, the details and the embodiments may vary, even significantly, with respect to what has been described by way of example only without departing from the scope of the embodiments.

The claims are an integral part of the technical teaching provided in respect of the embodiments.

The extent of protection is determined by the annexed claims.

1. A method, comprising:
mounting a semiconductor die onto a substrate with electrically conductive pillars arranged between an active surface of the semiconductor die and a die-mounting surface of the substrate, wherein the electrically conductive pillars provide electrical coupling between the semiconductor die and the substrate;
encapsulating the substrate and semiconductor die mounted thereon in an encapsulation of electrically insulating material, wherein the encapsulation of electrically insulating material has a first surface at the substrate and a second surface opposite said first surface;
removing electrically insulating material from the second surface of the encapsulation to expose a back surface of the semiconductor die opposite said active surface; and
then providing a thermally conductive layer in heat transfer relationship with said exposed back surface of the semiconductor die, wherein the thermally conductive layer facilitates dissipation of heat generated by the semiconductor die.

2. The method of claim 1, wherein removing electrically insulating encapsulation material from said second surface of the encapsulation to expose said back surface of the semiconductor die comprises performing one of a laser ablation or a grinding.

3. The method of claim 1, wherein the substrate comprises a leadframe or a laminate substrate.

4. The method of claim 1, wherein providing the thermally conductive layer in heat transfer relationship with said exposed back surface of the semiconductor die comprises performing an additive manufacturing technique.

5. The method of claim 4, wherein the additive manufacturing technique is laser induced forward transfer (LIFT).

6. The method of claim 1, further comprising providing the thermally conductive layer in heat transfer relationship with said exposed back surface of the semiconductor die with protrusions.

7. The method of claim 6, wherein said protrusions of the thermally conductive layer include one or more heat-dissipating fins.

8. The method of claim 1, wherein removing electrically insulating material from the second surface of the encapsulation comprises forming an opening in the electrically insulating material that exposes a portion of the back surface of the semiconductor die, and wherein providing the thermally conductive layer comprises installing the thermal conductive layer within the opening in heat transfer relationship with said portion of the back surface of the semiconductor die.

9. A device, comprising:
a semiconductor die mounted onto a substrate with electrically conductive pillars arranged between an active surface of the semiconductor die and a die-mounting surface of the substrate, wherein the electrically conductive pillars provide electrical coupling between the semiconductor die and the substrate;
an encapsulation of electrically insulating material encapsulating the substrate and the semiconductor die mounted thereon, wherein the encapsulation of electrically insulating material has a first surface at the substrate and a second surface opposite said first surface;
wherein the encapsulation includes an opening exposing a back surface of the semiconductor die opposite said active surface; and
a thermally conductive layer within said opening in heat transfer relationship with said exposed back surface of the semiconductor die, wherein the thermally conductive layer facilitates dissipation of heat generated by the semiconductor die.

10. The device of claim 9, wherein the substrate comprises a leadframe or a laminate substrate.

11. The device of claim 9, wherein the thermally conductive layer includes protrusion forming one or more heat-dissipating fins configured to further facilitate dissipation of heat generated by the semiconductor die.

12. A device, comprising:
a semiconductor die mounted onto a substrate with electrically conductive pillars arranged between an active surface of the semiconductor die and a die-mounting surface of the substrate, wherein the electrically conductive pillars provide electrical coupling between the semiconductor die and the substrate;
an encapsulation of electrically insulating material encapsulating the substrate and the semiconductor die mounted thereon, wherein the encapsulation of electrically insulating material has a first surface at the substrate and a second surface opposite said first surface and coplanar with a back surface of the semiconductor die opposite said active surface; and
a thermally conductive layer mounted to the coplanar second surface and back surface and in heat transfer relationship with said back surface of the semiconductor die, wherein the thermally conductive layer facilitates dissipation of heat generated by the semiconductor die.

13. The device of claim 12, wherein the substrate comprises a leadframe or a laminate substrate.

14. The device of claim 12, wherein the thermally conductive layer includes protrusion forming one or more heat-dissipating fins configured to further facilitate dissipation of heat generated by the semiconductor die.
